(19) United States
(12) Patent Application Publication
(10) Pub. No.: US 2025/0293075 A1
(43) Pub. Date: Sep. 18, 2025

(54) DIE BONDING FILM AND METHOD FOR MANUFACTURING SAME, DICING/DIE BONDING INTEGRATED FILM AND METHOD FOR MANUFACTURING SAME, AND METHOD FOR MANUFACTURING SEMICONDUCTOR DEVICE

(71) Applicant: Resonac Corporation, Minato-ku, Tokyo (JP)

(72) Inventors: Kenya MORIYA, Minato-ku, Tokyo (JP); Yuta HARADA, Minato-ku, Tokyo (JP); Kohei TANIGUCHI, Minato-ku, Tokyo (JP)

(21) Appl. No.: 18/859,997

(22) PCT Filed: Dec. 20, 2023
(86) PCT No.: PCT/JP2023/045805

§ 371 Date: Oct. 25, 2024

(30) Foreign Application Priority Data
Dec. 22, 2022 (JP) 2022-205889

(51) Int. Cl. H01L 21/683; H01L 21/78

(52) U.S. Cl. CPC H01L 21/6836; H01L 21/78; H01L 2221/68327; H01L 2221/68381

(57) ABSTRACT

A method for manufacturing a die bonding film includes a first step of preparing a raw material varnish containing silver-containing particles manufactured by a reductive method or silver-containing particles of which the surfaces are treated with a surface treatment agent, a glutaric acid, and an organic solvent, a second step of mixing the raw material varnish to obtain an adhesive varnish, and a third step of applying the adhesive varnish to a support film, and removing the organic solvent to obtain a die bonding film. The content of the silver-containing particles is 70% by mass or more, on the basis of the total solid content of the adhesive varnish.

### TECHNICAL FIELD

The present disclosure relates to a die bonding film and a method for manufacturing the same, a dicing/die bonding integrated film and a method for manufacturing the same, and a method for manufacturing a semiconductor device.

### BACKGROUND ART

In the related art, a semiconductor device is manufactured via the following steps. First, a semiconductor wafer is stuck to an adhesive sheet for dicing, and in this state, the semiconductor wafer is singulated into a semiconductor chip (a dicing step). After that, an ultraviolet irradiation step, a picking-up step, a crimping step, a die bonding step, and the like are performed. In Patent Literature 1, an adhesive/adhesive sheet (a dicing/die bonding integrated film) having a function of fixing the semiconductor wafer in the dicing step and a function of causing the semiconductor chip to adhere to a substrate in the die bonding step is disclosed. In the dicing step, by singulating the semiconductor wafer and a, it is possible to obtain a chip with an adhesive layer piece.

Recently, a device referred to as a power semiconductor device performing power control or the like has been widespread. In the power semiconductor device, heat is easily generated due to a current supplied, and an excellent heat dissipation property is required. In Patent Literature 2, a conductive die bonding film having a heat dissipation property after curing higher than a heat dissipation property before curing, and a dicing tape with a die bonding film (a dicing/die bonding integrated film) are disclosed.

### CITATION LIST

### Patent Literature

Patent Literature 1: JP 2008-218571 A
Patent Literature 2: JP 6396189 B2

### SUMMARY OF INVENTION

### Technical Problem

However, in the semiconductor device manufactured by using the die bonding film and the dicing/die bonding integrated film of the related art, the heat dissipation property is not sufficient, and there is still a room for improvement.

Therefore, an object of the present disclosure is to provide a die bonding film and a dicing/die bonding integrated film capable of manufacturing a semiconductor device excellent in a heat dissipation property.

### Solution to Problem

As a result of intensive studies of the present inventors to attain the object described above, it has been found that by a die bonding film containing silver-containing particles of which the surfaces are treated with a surface treatment agent, and a glutaric acid, the thermal conductivity of the die bonding film is improved, and the invention of the present disclosure has been completed.

The present disclosure provides a method for manufacturing a die bonding film according to [1] to [5], a method for manufacturing a dicing/die bonding integrated film according to [6], a method for manufacturing a semiconductor device according to [7], a die bonding film according to [8] to [10], and a dicing/die bonding integrated film according to [11].

[1] A method for manufacturing a die bonding film, including: a first step of preparing a raw material varnish containing silver-containing particles manufactured by a reductive method, a glutaric acid, and an organic solvent; a second step of mixing the raw material varnish to obtain an adhesive varnish; and a third step of applying the adhesive varnish to a support film, and removing the organic solvent to obtain a die bonding film, in which a content of the silver-containing particles is 70% by mass or more, on the basis of a total solid content of the adhesive varnish.

[2] A method for manufacturing a die bonding film, including: a first step of preparing a raw material varnish containing silver-containing particles of which surfaces are treated with a surface treatment agent, a glutaric acid, and an organic solvent; a second step of mixing the raw material varnish to obtain an adhesive varnish; and a third step of applying the adhesive varnish to a support film, and removing the organic solvent to obtain a die bonding film, in which a content of the silver-containing particles is 70% by mass or more, on the basis of a total solid content of the adhesive varnish.

[3] The method for manufacturing a die bonding film according to [1] or [2], in which the second step is a step of mixing the raw material varnish under a temperature condition of 50° C. or higher.

[4] The method for manufacturing a die bonding film according to any one of [1] to [3], in which the raw material varnish further contains a thermosetting resin, a curing agent, and an elastomer.

[5] The method for manufacturing a die bonding film according to any one of [1] to [3], in which the second step is a step of adding the thermosetting resin, the curing agent, and the elastomer to the mixed raw material varnish to obtain an adhesive varnish further containing the thermosetting resin, the curing agent, and the elastomer.

[6] A method for manufacturing a dicing/die bonding integrated film, including: preparing a dicing tape having a base material layer and a pressure-sensitive adhesive layer provided on the base material layer; and sticking the die bonding film manufactured by the method for manufacturing a die bonding film according to any one of [1] to [5] and the pressure-sensitive adhesive layer of the dicing tape to form an adhesive layer consisting of the die bonding film on the pressure-sensitive adhesive layer.

[7] A method for manufacturing a semiconductor device, including: sticking the adhesive layer of the dicing/die bonding integrated film manufactured by the method for manufacturing a dicing/die bonding integrated film according to [6] to a semiconductor wafer, singulating the semiconductor wafer and the adhesive layer; picking up a semiconductor chip with an adhesive layer piece from the dicing tape; and causing the semiconductor chip with an adhesive layer piece to adhere to a support member via the adhesive layer piece.

[8] A die bonding film, containing: silver-containing particles manufactured by a reductive method; and a glutaric acid, in which a content of the silver-containing particles is 70% by mass or more, on the basis of a total amount of the die bonding film.

[9] The die bonding film according to [8], further containing: a thermosetting resin; a curing agent; and an elastomer.

[10] The die bonding film according to [9], in which the thermosetting resin includes an epoxy resin that is liquid at 25° C.

[11] A dicing/die bonding integrated film, including: a dicing tape having a base material layer and a pressure-sensitive adhesive layer provided on the base material layer; and an adhesive layer consisting of the die bonding film according to any one of [8] to [10], disposed on the pressure-sensitive adhesive layer of the dicing tape.

### Advantageous Effects of Invention

According to the present disclosure, the die bonding film and the dicing/die bonding integrated film capable of manufacturing the semiconductor device excellent in the heat dissipation property are provided. In addition, according to the present disclosure, the method for manufacturing a die bonding film and the method for manufacturing a dicing/die bonding integrated film are provided. Further, according to the present disclosure, the method for manufacturing a semiconductor device using such a dicing/die bonding integrated film is provided.

### BRIEF DESCRIPTION OF DRAWINGS

FIG. 1 is a schematic cross-sectional view illustrating one embodiment of a die bonding film.

FIG. 2 is a schematic cross-sectional view illustrating one embodiment of a dicing/die bonding integrated film.

FIG. 3 is a schematic cross-sectional view illustrating one embodiment of a method for manufacturing a semiconductor device. FIGS. 3(a), 3(b), 3(c), 3(d), 3(e), and 3(f) are cross-sectional views schematically illustrating each step.

FIG. 4 is a schematic cross-sectional view illustrating one embodiment of a semiconductor device.

### DESCRIPTION OF EMBODIMENTS

Hereinafter, an embodiment of the present disclosure will be described suitably with reference to the drawings. However, the present disclosure is not limited to the following embodiment. In the following embodiment, constituents (also including steps and the like) thereof are not essential, unless otherwise specified. The sizes of the constituents in each of the drawings are conceptual, and a relative relationship of the size between the constituents is not limited to that illustrated in each of the drawings.

The same applies to numerical values and ranges thereof in this specification, which does not limit the present disclosure. In this specification, a numerical range represented by using “to” includes numerical values described before and after “to” as the minimum value and the maximum value, respectively. In numerical ranges described in stages in this specification, the upper limit value or the lower limit value described in one numerical range may be replaced with the upper limit value or the lower limit value of a numerical range described in the other stage. In addition, in the numerical range described in this specification, the upper limit value or the lower limit value of the numerical range may be replaced with values described in Examples.

In this specification, “(meth)acrylate” indicates at least one of acrylate or methacrylate corresponding thereto. The same also applies to other similar expressions such as “(meth)acryloyl”. In addition, “(poly)” indicates both cases with and without the prefix “poly”. In addition, “A or B” may include either A or B, or may include both thereof. In addition, only one type of materials exemplified below can be used alone, or two or more types thereof may be used in combination, unless otherwise specified. In a case where there are a plurality of substances corresponding to each component in a composition, the content of each component in the composition indicates the total amount of the plurality of substances in the composition, unless otherwise specified.

### [Die Bonding Film]

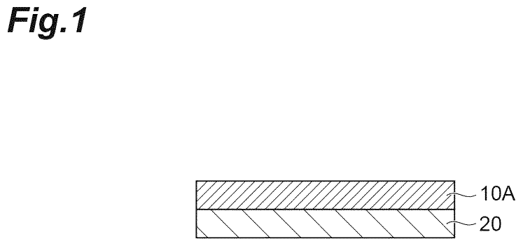

FIG. 1 is a schematic cross-sectional view illustrating one embodiment of a die bonding film. As illustrated in FIG. 1, a die bonding film 10A illustrated in FIG. 1 may be provided on a support film 20. The die bonding film 10A is thermosetting, and can be in a cured product (stage C) state after a curing treatment via a semi-cured (stage B) state.

The die bonding film 10A contains silver-containing particles (a component (a)) manufactured by a reductive method and a glutaric acid (a component (b)), and as necessary, may further contain a thermosetting resin (a component (c)), a curing agent (a component (d)), and an elastomer (a component (e)).

Component (a): silver-containing particles manufactured by a reductive method or silver-containing particles of which the surfaces are treated (covered) with a surface treatment agent

The component (a) is a component used to increase the thermal conductivity of the die bonding film, and is a component used to improve the heat dissipation property of a semiconductor device. The silver-containing particles, for example, may be particles composed of silver (particles configured of only silver, silver particles) or silver-coated metal particles in which the surfaces of the metal particles (such as copper particles) are covered with silver. Examples of the silver-coated metal particles include silver-coated copper particles and the like. The component (a) may be the particles composed of silver (the silver particles).

The component (a) may be the silver particles manufactured by the reductive method (silver particles manufactured by a liquid-phase (wet) reductive method using a reducing agent). In the liquid-phase (wet) reductive method using the reducing agent, in general, from the viewpoint of controlling a particle size and preventing aggregation and fusion, a surface treatment agent (a lubricant) is added, and the surfaces of the silver particles manufactured by the liquid-phase (wet) reductive method using the reducing agent are treated (covered) with the surface treatment agent (the lubricant). That is, the silver particles (the silver-containing particles) manufactured by the reductive method can be silver particles (silver-containing particles) of which the surfaces are treated (covered) with the surface treatment agent (the lubricant). Examples of the surface treatment agent include a fatty acid compound such as an oleic acid (Melting Point: 13.4° C.), a myristic acid (Melting Point: 54.4° C.), a palmitic acid (Melting Point: 62.9° C.), and a stearic acid (Melting Point: 69.9° C.), a fatty amide compound such as oleic amide (Melting Point: 76° C.) and stearic amide (Melting Point: 100° C.), an aliphatic alcohol compound such as pentanol (Melting Point: −78° C.), hexanol (Melting Point: −51.6° C.), oleyl alcohol (Melting Point: 16° C.), and stearyl alcohol (Melting Point: 59.4° C.), an aliphatic nitrile compound such as oleanitrile (Melting Point: −1° C.), and the like. The surface treatment agent may be a surface treatment agent having a low melting point (for example, a melting point of 100° C. or lower) and high solubility to an organic solvent, and for example, may be the fatty acid compound. That is, the component (a) is silver particles (silver-containing particles) of which the surfaces are treated (covered) with the fatty acid compound.

The shape of the component (a) is not particularly limited, and for example, the component (a) may be in the shape of a flake, a resin, a sphere, or the like, and may be in the shape of a sphere. In a case where the component (a) is in the shape of a sphere, there is a tendency that it is easy to obtain the die bonding film of which the surface roughness (Ra) is improved.

The average particle size of the component (a) may be 0.01 to 10 μm. In a case where the average particle size of the component (a) is 0.01 μm or more, there is a tendency that it is possible to prevent an increase in a viscosity when preparing an adhesive varnish, contain a desired amount of component (a) in the die bonding film, ensure the wettability of the die bonding film to an adherend, and exhibit more excellent adhesiveness. In a case where the average particle size of the component (a) is 10 μm or less, there is a tendency that it is more excellent in film moldability, and it is possible to improve the thermal conductivity by adding the component (a), and as a result thereof, it is possible to improve the heat dissipation property of the semiconductor device. In addition, according to such a range, there is a tendency that it is possible to further decrease the thickness of the die bonding film, make a semiconductor chip have a highly-stacked structure, and prevent the occurrence of a chip crack due to the protrusion of conductive particles from the die bonding film. The average particle size of the component (a) may be 0.1 μm or more, 0.5 μm or more, or 1.0 μm or more, and may be 8.0 μm or less, 5.0 μm or less, or 3.0 μm or less.

In this specification, the average particle size of the component (a) indicates a particle size (a 50% laser particle size (D₅₀)) when a ratio (a volume fraction) to the total volume of the component (a) is 50%. The average particle size (D₅₀) can be obtained by measuring a suspension liquid, in which the component (a) is suspended in water, by a laser scattering method using a laser diffraction particle size analyzer (for example, Microtrac).

The content of the component (a) is 70% by mass or more, on the basis of the total amount of the die bonding film (or the total solid content of the adhesive varnish described below). In a case where the content of the component (a) is 70% by mass or more, on the basis of the total amount of the die bonding film, it is possible to improve the thermal conductivity of the die bonding film, and as a result thereof, it is possible to improve the heat dissipation property. The content of the component (a) may be 72% by mass or more, 74% by mass or more, or 75% by mass or more, on the basis of the total amount of the die bonding film. The upper limit of the content of the component (a) is not particularly limited, and may be 90% by mass or less, 85% by mass or less, or 80% by mass or less, on the basis of the total amount of the die bonding film. In a case where the content of the component (a) is 90% by mass or less, on the basis of the total amount of the die bonding film, it is possible to more sufficiently contain other components in the die bonding film. Accordingly, it is possible to ensure the wettability of the die bonding film to the adherend, and exhibit more excellent adhesiveness.

The content of the component (a) may be 24.0% by volume or more, 24.5% by volume or more, or 25.0% by volume or more, on the basis of the total amount (the total volume) of the die bonding film. In a case where the content of the component (a) is 24.0% by volume or more, on the basis of the total amount (the total volume) of the die bonding film, it is possible to improve the thermal conductivity of the die bonding film, and as a result thereof, it is possible to improve the heat dissipation property of the semiconductor device. The content of the component (a) may be 33.0% by volume or less, 30.0% by volume or less, or 28.0% by volume or less, on the basis of the total amount (the total volume) of the die bonding film. In a case where the content of the component (a) is 33.0% by volume or less, on the basis of the total amount (the total volume) of the die bonding film, it is possible to more sufficiently contain other components in the die bonding film. Accordingly, it is possible to ensure the wettability of the die bonding film to the adherend, and exhibit more excellent adhesiveness.

The content (% by volume) of the component (a), for example, can be calculated from Expression (I) described below when the density of the die bonding film is x (g/cm³), the density of the component (a) is y (g/cm³), and a mass ratio of the component (a) in the die bonding film is z (% by mass). Note that the mass ratio of the component (a) in the die bonding film, for example, can be obtained by performing thermogravimetric analysis using a thermogravimeter-differential thermal analyzer (TG-DTA). In addition, the density of the die bonding film and the component (a) can be obtained by measuring the mass and the specific weight using a gravimeter.

$$Content ( \% by volume ) of Component ( a ) = ( x / y ) \times z \qquad ( I )$$

Measurement Condition of TG-DTA: a temperature range of 30 to 600° C. (a temperature increase rate of 30° C./minute), maintained at 600° C. for 20 minutes
Air Flow Rate: 300 mL/minute
Thermogravimeter-Differential Thermal Analyzer: manufactured by Seiko Instruments Inc., TG/DTA220
Gravimeter: manufactured by Alfa Mirage Co., Ltd., EW-300SG Component (b): Glutaric Acid

The die bonding film 10A contains the component (b). By the die bonding film containing the component (a) and the component (b), it is possible to improve the thermal conductivity of the die bonding film, and as a result thereof, it is possible to improve the heat dissipation property of the semiconductor device.

The content of the component (b) may be 0.1 to 5 parts by mass when the total amount of the component (a) is 100 parts by mass. In a case where the content of the component (b) is 0.1 parts by mass or more when the total amount of the component (a) is 100 parts by mass, there is a tendency that it is possible to further improve the thermal conductivity of the die bonding film. In a case where the content of the component (b) is 5 parts by mass or less when the total amount of the component (a) is 100 parts by mass, there is a tendency that it is possible to sufficiently ensure the amount of other components (in particular, the component (c), the component (d), and the component (e)), and it is excellent in film formability.

The content of the component (b) may be 0.2% by mass or more, or 0.3% by mass or more, and may be 3% by mass or less, or 2% by mass or less, on the basis of the total amount of the die bonding film (or the total solid content of the adhesive varnish described below).

### Component (c): Thermosetting Resin

The component (c) is a component having a property of being cured by forming a three-dimensional bond between molecules by heating or the like, and is a component exhibiting an adhesive action after curing. The component (c) may be an epoxy resin. The component (c) may include an epoxy resin that is liquid at 25° C. Any epoxy resin can be used without being particularly limited insofar as the epoxy resin has an epoxy group in the molecules. The epoxy resin may have two or more epoxy groups in the molecules.

Examples of the epoxy resin include a bisphenol A-type epoxy resin, a bisphenol F-type epoxy resin, a bisphenol S-type epoxy resin, a phenol novolac-type epoxy resin, a cresol novolac-type epoxy resin, a bisphenol A novolac-type epoxy resin, a bisphenol F novolac-type epoxy resin, a stilbene-type epoxy resin, a triazine skeleton-containing epoxy resin, a fluorene skeleton-containing epoxy resin, a triphenol methane-type epoxy resin, a biphenyl-type epoxy resin, a xylene-type epoxy resin, a biphenyl aralkyl-type epoxy resin, a naphthalene-type epoxy resin, a dicyclopentadiene-type epoxy resin, polyfunctional phenols, a diglycidyl ether compound of polycyclic aromatics such as anthracene, and the like. Among them, the epoxy resin, from the viewpoint of the heat resistance of a cured product, and the like, may be the bisphenol-type epoxy resin or the cresol novolac-type epoxy resin.

The epoxy resin may include an epoxy resin that is liquid at 25° C. (hereinafter, may be simply referred to as a “liquid epoxy resin”). By including such a liquid epoxy resin, there is a tendency that it is easy to obtain the die bonding film of which the surface roughness (Ra) is improved. Examples of a commercially available product of the liquid epoxy resin include EXA-830CRP (product name, manufactured by DIC Corporation), YDF-8170C (product name, manufactured by NIPPON STEEL Chemical & Material Co., Ltd.), and the like.

The epoxy equivalent of the epoxy resin is not particularly limited, and may be 90 to 300 g/eq, or 110 to 290 g/eq. In a case where the epoxy equivalent of the epoxy resin is in such a range, there is a tendency that it is easy to ensure the fluidity of an adhesive composition when forming the die bonding film while maintaining the bulk strength of the die bonding film.

The content of the component (c) may be 1% by mass or more, 3% by mass or more, or 5% by mass or more, and may be 15% by mass or less, 12% by mass or less, or 10% by mass or less, on the basis of the total amount of the die bonding film (or the total solid content of the adhesive varnish described below).

In a case where the component (c) includes the liquid epoxy resin, a mass ratio of the liquid epoxy resin to the total amount of the component (c) (Mass of Liquid Epoxy Resin/Total Mass of Component (c)) may be 20% or more, 30% or more, 40% or more, or 50% or more, and may be 100% or less, 90% or less, 80% or less, or 70% or more, in percentage.

### Component (d): Curing Agent

The component (d) may be a phenol resin that can be a curing agent of an epoxy resin. Any phenol resin can be used without being particularly limited insofar as the phenol resin has a phenolic hydroxyl group in the molecules. Examples of the phenol resin include a novolac-type phenol resin obtained by the condensation or the cocondensation of phenols such as phenol, cresol, resorcine, catechol, bisphenol A, bisphenol F, phenyl phenol, and aminophenol and/or naphthols such as α-naphthol, β-naphthol, and dihydroxynaphthalene, and a compound having an aldehyde group, such as formaldehyde, under an acidic catalyst, a phenol aralkyl resin synthesized from phenols such as allylated bisphenol A, allylated bisphenol F, allylated naphthalene diol, phenol novolac, and phenol and/or naphthols, and dimethoxyparaxylene or bis(methoxymethyl) biphenyl, a naphthol aralkyl resin, a biphenyl aralkyl-type phenol resin, a phenyl aralkyl-type phenol resin, and the like.

The hydroxyl equivalent of the phenol resin may be 40 to 300 g/eq, 70 to 290 g/eq, or 100 to 280 g/eq. In a case where the hydroxyl equivalent of the phenol resin is 40 g/eq or more, there is a tendency that the storage modulus of the film is further improved, and in a case where the hydroxyl equivalent is 300 g/eq or less, the occurrence of foam formation and outgasing can be further suppressed.

A ratio (Epoxy Equivalent of Epoxy Resin as Component (c)/Hydroxyl Equivalent of Phenol Resin as Component (d)) of the epoxy equivalent of the epoxy resin that is the component (c) to the hydroxyl equivalent of the phenol resin that is the component (d), from the viewpoint of curability, 0.30/0.70 to 0.70/0.30, 0.35/0.65 to 0.65/0.35, 0.40/0.60 to 0.60/0.40, or 0.45/0.55 to 0.55/0.45. In a case where the equivalent ratio is 0.30/0.70 or more, there is a tendency that more sufficient curability is obtained. In a case where the equivalent ratio is 0.70/0.30 or less, it is possible to prevent the viscosity from excessively increasing, and obtain more sufficient fluidity.

The content of the component (d) may be 1% by mass or more, 3% by mass or more, or 5% by mass or more, and may be 15% by mass or less, 12% by mass or less, or 10% by mass or less, on the basis of the total amount of the die bonding film (or the total solid content of the adhesive varnish described below).

### Component (e): Elastomer

Examples of the component (e) include a polyimide resin, an acrylic resin, a urethane resin, a polyphenylene ether resin, a polyether imide resin, a phenoxy resin, a modified polyphenylene ether resin, and the like. The component (e) may be such resins, may be a resin having a cross-linkable functional group, or may be an acrylic resin having a cross-linkable functional group. Here, the acrylic resin indicates a polymer having a constitutional unit derived from (meth)acrylic acid ester. The acrylic resin may be a polymer having, as a constitutional unit, a constitutional unit derived from (meth)acrylic acid ester having a cross-linkable functional group such as an epoxy group, an alcoholic or phenolic hydroxyl group, and a carboxy group. In addition, the acrylic resin may be acrylic rubber such as a copolymer of (meth)acrylic acid ester and acryl nitrile.

Examples of a commercially available product of the acrylic resin include SG-70L, SG-708-6, WS-023 EK30, SG-280 EK23, HTR-860P-3, HTR-860P-3CSP, and HTR-860P-3CSP-3 DB (all are manufactured by Nagase ChemteX Corporation), and the like.

The glass transition temperature (Tg) of the component (e) may be −50 to 50° C., or −30 to 20° C. In a case where Tg of the acrylic resin is −50° C. or higher, since the tackiness of the die bonding film decreases, there is a tendency that handleability is further improved. In a case where Tg of the acrylic resin is 50° C. or lower, there is a tendency that it is possible to more sufficiently ensure the fluidity of the adhesive composition when forming the die bonding film. Here, Tg of the component (e) indicates a value measured by using a thermal differential scanning calorimetry (DSC) (for example, manufactured by Rigaku Corporation, product name: Thermo Plus 2).

The weight average molecular weight (Mw) of the component (e) may be 50000 to 1600000, 100000 to 1400000, or 300000 to 1200000. In a case where Mw of the component (e) is 50000 or more, there is a tendency that it is more excellent in the film formability. In a case where Mw of the component (e) is 1600000 or less, there is a tendency that it is more excellent in the fluidity of the adhesive composition when forming the die bonding film. Note that Mw is a value obtained by measurement using a gel permeation chromatography (GPC), and conversion using a calibration curve of standard polystyrene.

A measurement device, a measurement condition, and the like of Mw of the component (e), for example, are as described below.
Pump: L-6000 (manufactured by Hitachi, Ltd.)
Column: a column in which Gelpack GL-R440 (manufactured by Showa Denko Materials Co., Ltd.), Gelpack GL-R450 (manufactured by Showa Denko Materials Co., Ltd.), and Gelpack GL-R400M (manufactured by Showa Denko Materials Co., Ltd.) (each having 10.7 mm (Diameter)×300 mm) are connected in this order
Eluent: tetrahydrofuran (hereinafter, referred to as “THF”)
Sample: a solution in which 120 mg of a specimen is dissolved in 5 mL of THF
Flow Rate: 1.75 mL/minute

The content of the component (e) may be 1% by mass or more, 3% by mass or more, or 5% by mass or more, and may be 15% by mass or less, 12% by mass or less, or 10% by mass or less, on the basis of the total amount of the die bonding film (or the total solid content of the adhesive varnish described below).

### Component (f): Curing Accelerator

The die bonding film 10A may further contain a curing accelerator (the component (f)). By the die bonding film containing the component (f), there is a tendency that it is possible to make the adhesiveness and connection reliability more compatible. Examples of the component (f) include imidazoles and derivatives thereof, an organic phosphorus-based compound, secondary amines, tertiary amines, a quaternary ammonium salt, and the like. Among them, the component (f), from the viewpoint of reactivity, may be the imidazoles and the derivatives thereof.

Examples of the imidazoles include 2-methyl imidazole, 1-benzyl-2-methyl imidazole, 1-cyanoethyl-2-phenyl imidazole, 1-cyanoethyl-2-methyl imidazole, and the like.

The content of the component (f) may be 0.001 to 1% by mass, on the basis of the total amount of the die bonding film (or the total solid content of the adhesive varnish described below). In a case where the content of the component (f) is in such a range, there is a tendency that it is possible to make the adhesiveness and the connection reliability more compatible.

The die bonding film 10A may further contain a coupling agent, an antioxidant agent, a rheological control agent, a leveling agent, and the like, as other components in addition to the component (a) to the component (f). Examples of the coupling agent include 3-ureidopropyl triethoxysilane, 3-mercaptopropyl trimethoxysilane, 3-phenyl aminopropyl trimethoxysilane, 3-(2-aminoethyl) aminopropyl trimethoxysilane, and the like. The content of the other component may be 0.01 to 3% by mass, on the basis of the total amount of the die bonding film.

### [Method for Manufacturing Die Bonding Film]

The die bonding film 10A illustrated in FIG. 1 can be obtained by a method including a first step of preparing a raw material varnish containing the component (a) (the silver-containing particles manufactured by the reductive method or the silver-containing particles of which the surfaces are treated with the surface treatment agent), the component (b), and an organic solvent, a second step of mixing the raw material varnish to obtain an adhesive varnish, and a third step applying the adhesive varnish to a support film, and removing the organic solvent to obtain a die bonding film.

The first step is a step of preparing the raw material varnish containing the component (a) (the silver-containing particles manufactured by the reductive method or the silver-containing particles of which the surfaces are treated with the surface treatment agent), the component (b), and the organic solvent.

The organic solvent is not particularly limited insofar as the components other than the component (a) can be dissolved in the organic solvent. Examples of the organic solvent include aromatic hydrocarbon such as toluene, xylene, mesitylene, cumene, and p-cymene; aliphatic hydrocarbon such as hexane and heptane; cyclic alkane such as methyl cyclohexane; cyclic ether such as tetrahydrofuran and 1,4-dioxane; ketone such as acetone, methyl ethyl ketone, methyl isobutyl ketone, cyclohexanone, and 4-hydroxy-4-methyl-2-pentanone; ester such as methyl acetate, ethyl acetate, butyl acetate, methyl lactate, ethyl lactate, and γ-butyrolactone; carbonic acid ester such as ethylene carbonate and propylene carbonate; amide such as N,N-dimethyl formamide, N,N-dimethyl acetamide, and N-methyl-2-pyrrolidone, and the like. Among them, the organic solvent, from the viewpoint of solubility and a boiling point, may be the toluene, the xylene, the methyl ethyl ketone, the methyl isobutyl ketone, or the cyclohexanone. A solid content concentration in the raw material varnish may be 10 to 80% by mass, on the basis of the total amount of the raw material varnish.

The raw material varnish, for example, can be obtained by adding each component to a container used with a stirrer. In this case, the addition order of each component is not particularly limited, and can be suitably set in accordance with the property of each component.

The second step is a step of mixing the raw material varnish to obtain the adhesive varnish.

Mixing can be performed by suitably combining general stirrers such as a homodispenser, a three-one-motor, a mixing rotor, a planetary stirrer, and a mortar machine. The stirrer may include warming equipment such as a heater unit capable of managing the temperature condition of the raw material varnish (or the adhesive varnish). In the case of performing mixing with the homodispenser, the number of rotations of the homodispenser may be 4000 rotations/minute or more.

The second step may be a step of mixing the raw material varnish under a temperature condition of 50° C. or higher. A mixing temperature, as necessary, may be adjusted by using warming equipment, heat-retaining equipment, and the like. In a case where the mixing temperature is 50° C. or higher, for example, the obtained die bonding film is likely to form a sintered body of the component (a) in the cured product (stage C) state after the curing treatment, and the thermal conductivity of the die bonding film can be further improved. The mixing temperature may be 55° C. or higher, 60° C. or higher, 65° C. or higher, or 70° C. or higher. The upper limit of the mixing temperature, for example, may be 120° C. or lower, 110° C. or lower, 100° C. or lower, 90° C. or lower, or 80° C. or lower. A mixing time, for example, may be 1 minute or longer, 5 minutes or longer, 10 minutes or longer, or 20 minutes or longer, and may be 80 minutes or shorter, 60 minutes or shorter, or 40 minutes or shorter.

The component (c), the component (d), the component (e), the component (f), and the other component can be each independently contained in the raw material varnish or the adhesive varnish in an arbitrary step, in accordance with the property of each component. For example, in the first step, the raw material varnish further containing such components may be prepared, and in the second step, the raw material varnish may be mixed to obtain the adhesive varnish containing the component (a), the component (b), the component (c), the component (d), the component (e), the component (f), and the other component. In addition, for example, in the first step, the raw material varnish may be prepared, and in the second step, the raw material varnish may be mixed, and such components may be added to the mixed raw material varnish to obtain the adhesive varnish containing the component (a), the component (b), the component (c), the component (d), the component (e), the component (f), and the other component. Further, for example, in the first step, the raw material varnish further containing the component (c) and the component (d) may be prepared, and in the second step, the raw material varnish may be mixed, and the component (e), the component (f), and the other component may be added to the mixed raw material varnish to obtain the adhesive varnish containing the component (a), the component (b), the component (c), the component (d), the component (e), the component (f), and the other component. In a case where at least one type of component selected from the group consisting of the component (c), the component (d), the component (e), the component (f), and the other component is added to the mixed raw material varnish in the second step, for example, mixing may be performed under a temperature condition of lower than 50° C. (for example, a room temperature (25° C.)), after the component is added. In this case, the mixing condition may be a room temperature (25° C.) for 0.1 to 48 hours.

As described above, it is possible to obtain the adhesive varnish containing a predetermined component. In the obtained adhesive varnish, air bubbles in the varnish may be removed by vacuum deaeration or the like.

The content of the silver-containing particles is 70% by mass or more, on the basis of the total solid content of the adhesive varnish. In this specification, the solid content of the adhesive varnish indicates the total amount of the components other than the organic solvent.

The third step is a step of applying the adhesive varnish to the support film 20, and removing the organic solvent to obtain the die bonding film 10A.

The support film 20 is not particularly limited, and examples thereof include films such as polytetrafluoroethylene, polyethylene, polypropylene, polymethyl pentene, polyethylene terephthalate, and polyimide. The support film may be subjected to a mold release treatment. The thickness of the support film 20, for example, may be 10 to 200 μm, or 20 to 170 μm.

As a method for applying the adhesive varnish to the support film 20, a known method can be used, and examples thereof include a knife coating method, a roll coating method, a spray coating method, a gravure coating method, a bar coating method, a curtain coating method, and the like.

The organic solvent after the adhesive varnish is applied to the support film can be removed by heating and drying. Heating and drying are not particularly limited insofar as the used organic solvent is sufficiently volatilized, and for example, a heating and drying temperature may be 50 to 200° C., and a heating and drying time may be 0.1 to 30 minutes. Heating and drying may be gradually performed at different heating and drying temperatures or for different heating and drying times.

The thickness of the die bonding film 10A can be suitably adjusted in accordance with the intended use, and for example, may be 3 to 200 μm. In a case where the thickness of the die bonding film 10A is 3 μm or more, there is a tendency that an adhesive strength with a semiconductor wafer is sufficient, and in a case where the thickness is 200 μm or less, there is a tendency that the thermal conductivity is sufficient. The thickness of the die bonding film 10A, from the viewpoint of the adhesive strength and the thinning of the semiconductor device, may be 5 to 100 μm, or 10 to 50 μm.

The thermal conductivity (25° C.±1° C.) of the die bonding film 10A after being thermally cured at 170° C. for 3 hours (in the stage C state) may be 4.0 W/m·K or more. In a case where the thermal conductivity is 4.0 W/m·K or more, there is a tendency that the heat dissipation property of the semiconductor device is more excellent. The thermal conductivity may be 4.5 W/m·K or more, 5.0 W/m·K or more, 5.5 W/m·K or more, or 6.0 W/m·K or more. The upper limit of the thermal conductivity (25° C.±1° C.) of the die bonding film 10A in the stage C state is not particularly limited, and may be 30 W/m·K or less.

The thermal conductivity (25° C.±1° C.) of the die bonding film 10A after being thermally cured at 170° C. for 3 hours (in the stage C state), for example, can be measured by the following method. First, the die bonding film is cut to have a predetermined size, and a predetermined number of film pieces are prepared such that the thickness when stacking the film pieces is 200 μm. For example, in the case of using a die bonding film with a thickness of 25 μm, eight film pieces are prepared. In the case of using a die bonding film with a thickness of 10 μm, 20 film pieces are prepared. By laminating such film pieces on a hot plate at 70° C. using a rubber roll, a stacked body with a thickness of 200 μm is prepared. Next, each stacked body is thermally cured at 170° C. for 3 hours in a clean oven (manufactured by ESPEC CORP.) to obtain a specimen in the stage C state. The obtained specimen is cut to 1 cm×1 cm, which is used as a film for measuring a thermal conductivity to measure the thermal conductivity in the following measurement items/conditions.

### (Calculation of Thermal Conductivity)

The thermal conductivity 2 of the film for measuring a thermal conductivity in a thickness direction is calculated by the following expression.

$$Thermal conductivity λ ( W / m \cdot K ) = Thermal diffusivity α ( {m}^{2} / s ) \times Specific heat Cp ( J / kg \cdot K ) \times Density ρ ( g / {cm}^{3} )$$

Note that the thermal diffusivity α, the specific heat Cp, and the density ρ are measured by the following method. A high thermal conductivity λ indicates a more excellent heat dissipation property in the semiconductor device.

### (Measurement of Thermal Diffusivity α)

Both surfaces of the film for measuring a thermal conductivity are subjected to a blackening treatment by graphite spray to prepare a measurement sample. For the measurement sample, for example, the thermal diffusivity α of the film for measuring a thermal conductivity is obtained by a laser flash method (a xenon flash method) using the following measurement device in the following condition.
Measurement Device: a thermal diffusivity measurement device (manufactured by NETZSCH Japan K.K., product name: LFA447 nanoflash)
Pulse width of pulsed light irradiation: 0.1 ms
Applied voltage of pulsed light irradiation: 236 V
Treatment of measurement sample: both surfaces of the film for measuring a thermal conductivity are subjected to the blackening treatment by the graphite spray
Measurement ambient temperature: 25° C.±1° C.

### (Measurement of Specific Heat Cp (25° C.))

The specific heat Cp (25° C.) of the film for measuring a thermal conductivity, for example, is obtained by performing differential scanning calorimetry (DSC) using the following measurement device in the following condition.
Measurement device: a differential scanning calorimeter (manufactured by PerkinElmer, Inc., product name: Pyris1)
Reference substance: sapphire
Temperature increase rate: 10° C./minute
Temperature increase range: a room temperature (25° C.) to 60° C.

### (Measurement of Density ρ)

The density ρ of the film for measuring a thermal conductivity, for example, is measured by Archimedes' principle using the following measurement device in the following condition.
Measurement device: an electronic gravimeter (manufactured by Alfa Mirage Co., Ltd., product name: SD200L)
Water temperature: 25° C.

By the die bonding film containing the component (a) and the component (b), it is possible to improve the thermal conductivity, and as a result thereof, it is possible to improve the heat dissipation property of the semiconductor device. Therefore, the die bonding film can be preferably used as a dicing/die bonding integrated film, in combination with a dicing film having a pressure-sensitive adhesive layer.

### [Dicing/Die Bonding Integrated Film]

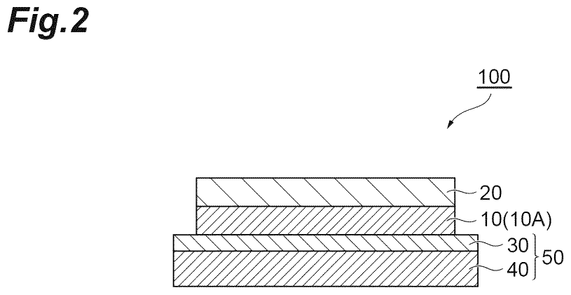

FIG. 2 is a schematic cross-sectional view illustrating one embodiment of a dicing/die bonding integrated film. A dicing/die bonding integrated film 100 illustrated in FIG. 2 includes a dicing tape 50 (a dicing film) including a base material layer 40 and a pressure-sensitive adhesive layer 30 provided on the base material layer 40, and an adhesive layer 10 consisting of the die bonding film 10A provided on the pressure-sensitive adhesive layer 30 of the dicing tape 50. The dicing/die bonding integrated film 100 may be in the shape of a film, a sheet, a tape, or the like. The dicing/die bonding integrated film 100 may include the support film 20 on the surface of the adhesive layer 10 on a side opposite to the pressure-sensitive adhesive layer 30.

Examples of the base material layer 40 in the dicing tape 50 include a plastic film such as a polytetrafluoroethylene film, a polyethylene terephthalate film, a polyethylene film, a polypropylene film, a polymethyl pentene film, and a polyimide film, and the like. In addition, the base material layer 40, as necessary, may be subjected to a surface treatment such as primer application, a UV treatment, a corona discharge treatment, a grinding treatment, and an etching treatment.

The pressure-sensitive adhesive layer 30 in the dicing tape 50 is not particularly limited insofar as the pressure-sensitive adhesive layer has a sufficient adhesive force to prevent the scattering of the semiconductor chip when diced, and has a low adhesive force not to damage the semiconductor chip in the subsequent picking-up step of the semiconductor chip, and any pressure-sensitive adhesive layer of the related art known in the field of a dicing tape can be used. The pressure-sensitive adhesive layer 30 may be a pressure-sensitive adhesive layer consisting of a non-ultraviolet curable pressure-sensitive adhesive agent, or may be a pressure-sensitive adhesive layer consisting of an ultraviolet curable pressure-sensitive adhesive agent. In a case where the pressure-sensitive adhesive layer is the pressure-sensitive adhesive layer consisting of the ultraviolet curable pressure-sensitive adhesive agent, it is possible to decrease the adhesiveness of the pressure-sensitive adhesive layer by the irradiation of an ultraviolet ray.

The thickness of the dicing tape 50 (the base material layer 40 and the pressure-sensitive adhesive layer 30), from the viewpoint of an economic efficiency and the handleability of the film, may be 60 to 150 μm, or 70 to 130 μm.

The dicing/die bonding integrated film 100 illustrated in FIG. 2 can be obtained by a manufacturing method including preparing the die bonding film 10A, and the dicing tape 50 including the base material layer 40 and the pressure-sensitive adhesive layer 30 provided on the base material layer 40, and sticking the die bonding film 10A and the pressure-sensitive adhesive layer 30 of the dicing tape 50. As a method for sticking the die bonding film 10A and the pressure-sensitive adhesive layer 30 of the dicing tape 50, a known method can be used.

### [Semiconductor Device and Method for Manufacturing Same]

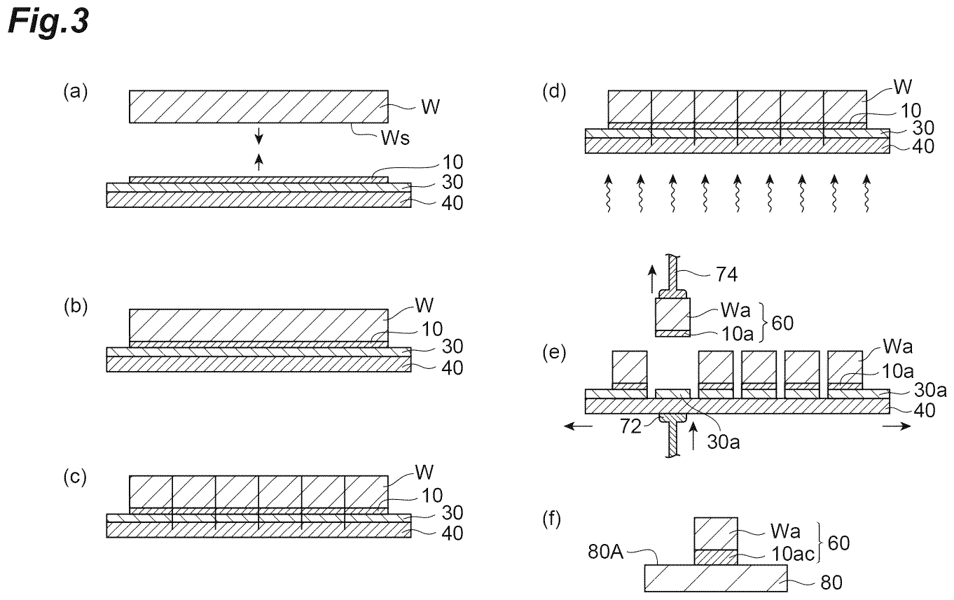

FIG. 3 is a schematic cross-sectional view illustrating one embodiment of a method for manufacturing a semiconductor device. FIGS. 3(a), 3(b), 3(c), 3(d), 3(e), and 3(f) are cross-sectional views schematically illustrating each step. The method for manufacturing a semiconductor device includes sticking a semiconductor wafer W to the adhesive layer 10 of the dicing/die bonding integrated film 100 (a wafer lamination step, refer to FIGS. 3(a) and 3(b)), singulating the semiconductor wafer W and the adhesive layer 10 (a dicing step, refer to FIG. 3(c)), and as necessary, irradiating the pressure-sensitive adhesive layer 30 with an ultraviolet ray (via the base material layer 40) (an ultraviolet irradiation step, refer to FIG. 3(d)), picking up a semiconductor chip 60 with an adhesive layer piece from (the pressure-sensitive adhesive layer 30 of) the dicing tape 50 (a picking-up step, refer to FIG. 3(e)), causing the semiconductor chip 60 with an adhesive layer piece to adhere to a support member 80 via an adhesive layer piece 10a (a semiconductor chip adhesion step, refer to FIG. 3(f)), and as necessary, thermally curing the adhesive layer piece 10a of the semiconductor chip 60 with an adhesive layer piece, which adheres to the support member 80 (a thermal curing step).

### <Wafer Lamination Step>

In this step, first, the dicing/die bonding integrated film 100 is disposed in a predetermined device. Subsequently, a surface Ws of the semiconductor wafer W is stuck to the adhesive layer 10 of the dicing/die bonding integrated film 100 (refer to FIGS. 3(a) and 3(b)). The circuit surface of the semiconductor wafer W may be provided on a side opposite to the surface Ws.

Examples of the semiconductor wafer W include monocrystal silicon, polycrystalline silicon, various ceramics, a compound such as gallium arsenide, and the like.

### <Dicing Step>

In this step, the semiconductor wafer W and the adhesive layer 10 are singulated by dicing (refer to FIG. 3(c)). In this case, a part of the pressure-sensitive adhesive layer 30, or the entire pressure-sensitive adhesive layer 30 and a part of the base material layer 40 may be singulated by dicing. As described above, the dicing/die bonding integrated film 100 also functions as a dicing sheet.

### <Ultraviolet Irradiation Step>

In a case where the pressure-sensitive adhesive layer 30 is the pressure-sensitive adhesive layer consisting of the ultraviolet curable pressure-sensitive adhesive agent, the method for manufacturing a semiconductor device may include the ultraviolet irradiation step. In this step, the pressure-sensitive adhesive layer 30 is irradiated with the ultraviolet ray (via the base material layer 40) (refer to FIG. 3(d)). In the ultraviolet irradiation, the wavelength of the ultraviolet ray may be 200 to 400 nm. In an ultraviolet irradiation condition, an illuminance and an irradiation amount may be in a range of 30 to 240 mW/cm² and in a range of 50 to 500 mJ/cm², respectively.

### <Picking-Up Step>

In this step, while the base material layer 40 is expanded to separate the singulated semiconductor chips 60 with an adhesive layer piece from each other, the semiconductor chip 60 with an adhesive layer piece, which is thrust by a needle 72 from the base material layer 40 side, is sucked with a suction collet 74, and the semiconductor chip 60 with an adhesive layer piece is picked up from a pressure-sensitive adhesive layer 30a (refer to FIG. 3(e)). Note that the semiconductor chip 60 with an adhesive layer piece has the semiconductor chip Wa and the adhesive layer piece 10a. The semiconductor chip Wa is obtained by singulating the semiconductor wafer W, and the adhesive layer piece 10a is obtained by singulating the adhesive layer 10. In addition, the pressure-sensitive adhesive layer 30a is obtained by singulating the pressure-sensitive adhesive layer 30. The pressure-sensitive adhesive layer 30a may remain on the base material layer 40 after picking up the semiconductor chip 60 with an adhesive layer piece. In this step, it is not necessary to expand the base material layer 40, but by expanding the base material layer 40, it is possible to further improve a picking-up property.

The amount of thrust by the needle 72 can be suitably set. Further, from the viewpoint of ensuring a sufficient picking-up property for an extremely thin wafer, for example, two or three stages of thrust may be performed. In addition, the semiconductor chip 60 with an adhesive layer piece may be picked up by a method other than the method using the suction collet 74.

### <Semiconductor Chip Adhesion Step>

In this step, the picked-up semiconductor chip 60 with an adhesive layer piece adheres to the support member 80 via the adhesive layer piece 10a by thermal crimping (refer to FIG. 3(f)). A plurality of semiconductor chips 60 with an adhesive layer piece may adhere to the support member 80.

A heating temperature in the thermal crimping, for example, may be 80 to 160° C. A load in the thermal crimping, for example, may be 5 to 15 N. A heating time in the thermal crimping, for example, may be 0.5 to 20 seconds.

### <Thermal Curing Step>

In this step, the adhesive layer piece 10a of the semiconductor chip 60 with an adhesive layer piece, which adheres to the support member 80, is thermally cured. By (further) thermally curing the adhesive layer piece 10a or a cured product 10ac of the adhesive layer piece, which causes the semiconductor chip Wa and the support member 80 to adhere to each other, stronger bonding adhesion and fixation are available. In addition, in a case where the component (a) is the silver particles (preferably the silver particles manufactured by the reductive method), by (further) thermally curing the adhesive layer piece 10a or the cured product 10ac of the adhesive layer piece, there is a tendency that the sintered body of the silver particles is more easily obtained. In the case of performing thermal curing, curing may be performed while applying a pressure. A heating temperature in this step can be suitably changed in accordance with the constituent of the adhesive layer piece 10a. The heating temperature, for example, may be 60 to 200° C., 90 to 190° C., or 120 to 180° C. A heating time may be 30 minutes to 5 hours, 1 to 3 hours, or 2 to 3 hours. Note that curing may be performed while gradually changing the temperature or the pressure.

The adhesive layer piece 10a is cured via the semiconductor chip adhesion step or the thermal curing step to be the cured product 10ac of the adhesive layer piece. In a case where the component (a) is the silver particles (preferably the silver particles manufactured by the reductive method), the cured product 10ac of the adhesive layer piece may contain the sintered body of the silver particles. Therefore, the semiconductor device to be obtained may have an excellent heat dissipation property.

The method for manufacturing a semiconductor device, as necessary, may include electrically connecting the tip end of a terminal portion (an inner lead) of the support member and an electrode pad on the semiconductor chip by a bonding wire (a wire bonding step). As the bonding wire, for example, a gold wire, an aluminum wire, a copper wire, or the like is used. A temperature when performing wire bonding may be in a range of 80 to 250° C. or 80 to 220° C. A heating time may be several seconds to several minutes. Wire bonding may be performed by using vibrational energy due to an ultrasonic wave and crimping energy due to an applied pressure together, in the state of being heated in the temperature range described above.

The method for manufacturing a semiconductor device, as necessary, may include sealing the semiconductor chip with a sealing material (a sealing step). This step is performed in order to protect the semiconductor chip or the bonding wire mounted on the support member. This step can be performed by molding a resin for sealing (a sealing resin) with a metallic mold. The sealing resin, for example, may be an epoxy-based resin. The support member and the residue are embedded by the heat and the pressure during sealing, and it is possible to prevent peeling due to air bubbles on the adhesive interface.

The method for manufacturing a semiconductor device, as necessary, may include completely curing the sealing resin that is insufficiently cured in the sealing step (a post-curing step). Even in a case where the adhesive layer piece is not thermally cured in the sealing step, in this step, the thermal curing of the adhesive layer piece is performed together with the curing of the sealing resin to make the bonding adhesion and fixation available. A heating temperature in this step can be suitably set in accordance with the type of sealing resin, and for example, may be in a range of 165 to 185° C., and a heating time may be approximately 0.5 to 8 hours.

The method for manufacturing a semiconductor device, as necessary, may include heating the semiconductor chip with an adhesive layer piece, which adheres to the support member, by using a reflow furnace (a heating and melting step). In this step, the semiconductor device sealed with the resin may be surface-mounted on the support member. Examples of a surface mounting method include reflow soldering in which solder is supplied in advance onto a printed wiring board, and then, heated and melted with warm air or the like to perform soldering, and the like. Examples of a heating method include hot-air reflow, infrared reflow, and the like. In addition, the heating method may be a method for performing heating entirely, or may be a method for performing heating locally. A heating temperature, for example, may be in a range of 240 to 280° C.

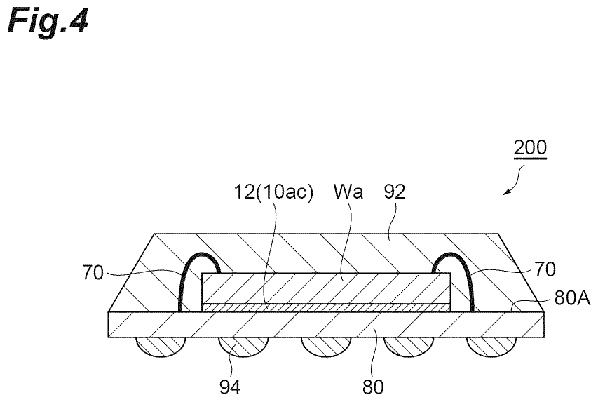

FIG. 4 is a schematic cross-sectional view illustrating one embodiment of a semiconductor device. A semiconductor device 200 illustrated in FIG. 4 includes the semiconductor chip Wa, the support member 80 on which the semiconductor chip Wa is mounted, and an adhesive member 12. The adhesive member 12 is provided between the semiconductor chip Wa and the support member 80 such that the semiconductor chip Wa and the support member 80 adhere to each other. The adhesive member 12 is a cured product of the die bonding film (the cured product 10ac of the adhesive layer piece). A connecting terminal (not illustrated) of the semiconductor chip Wa may be electrically connected to an external connecting terminal (not illustrated) via a wire 70. The semiconductor chip Wa may be sealed with a sealing material layer 92 formed from the sealing material. A solder ball 94 may be formed on the surface of the support member 80 on a side opposite to a surface 80A in order for electrical connection with an external substrate (a motherboard) (not illustrated).

The semiconductor chip Wa, for example, may be an integrated circuit (IC) or the like. Examples of the support member 80 include a lead frame such as a 42-alloy lead frame and a copper lead frame; a plastic film such as a polyimide resin and an epoxy resin; a modified plastic film obtained by impregnating a glass non-woven fabric or the like with plastics such as a polyimide resin and an epoxy resin, and performing curing; ceramics such as alumina, and the like.

The semiconductor device 200 includes the cured product of the die bonding film as the adhesive member, thereby having an excellent heat dissipation property.

### EXAMPLES

Hereinafter, the present disclosure will be described in detail, on the basis of Examples, but the present disclosure is not limited thereto.

### Reference Example 1, Examples 1 to 3, and Comparative Examples 1 to 7

### [Preparation of Die Bonding Film]

### <Preparation of Adhesive Varnish>

Cyclohexanone, as an organic solvent, was added to a component (a), a component (b) or a component (b′), a component (c), a component (d), and a component (e), as with a symbol and a composition ratio (Unit: parts by mass) shown in Table 1 and Table 2, to prepare a mixed varnish. The mixed varnish was stirred at 4000 rotations/minute for 20 minutes in a mixing temperature condition of 70° C. by using a homodispenser (manufactured by Tajima-KK., T.K.HOMO MIXER MARK II). Next, the mixed varnish was left to stand until the temperature was 20 to 30° C., and then, a component (f) and a component (g) were added to the mixed varnish, and stirred overnight at 250 rotations/minute by using a three-one-motor. As described above, each adhesive varnish of Reference Example 1, Examples 1 to 3, and Comparative Examples 1 to 7 was prepared in which the total content of the component (a), the component (b) or the component (b′), the component (c), the component (d), the component (e), the component (f), and the component (g) was 61 to 62% by mass.

The symbol of each component in Table 1 and Table 2 indicates the followings.

Component (a): silver-containing particles manufactured by a reductive method (silver-containing particles of which the surfaces were treated (covered) with a surface treatment agent)
(a-1) silver particles AG-3-1F (product name, manufactured by DOWA Electronics Materials Co., Ltd., shape: a sphere, average particle size (50% laser particle size (D₅₀)): 1.4 μm)
   Component (b) or Component (b′):
(b-1) a glutaric acid
(b′-1) a suberic acid
(b′-2) an azelaic acid
(b′-3) a propionic acid
(b′-4) an oxalic acid
(b′-5) a malonic acid
(b′-6) a maleic acid
(b′-7) an adipic acid

### Component (c): Thermosetting Resin

(c-1) N-500P-10 (product name, manufactured by DIC Corporation, a cresol novolac-type epoxy resin, epoxy equivalent: 204 g/eq, softening point: 84° C.)
(c-2) EXA-830CRP (product name, manufactured by DIC Corporation, a bisphenol F-type epoxy resin, epoxy equivalent: 159 g/eq, liquid at 25° C.)

### Component (d): Curing Agent

(d-1) MEH-7800M (product name, manufactured by MEIWA KAGAKU KOUGYOU CO., LTD., a phenyl aralkyl-type phenol resin, hydroxyl equivalent: 174 g/eq, Softening Point: 80° C.)

### Component (e): Elastomer

(e-1) HTR-860P-3CSP (product name, manufactured by Nagase ChemteX Corporation, acrylic rubber, weight average molecular weight: 800000, Tg: −7° C.)

### Component (f): Curing Accelerator

(f-1) 1B2MZ (product name, manufactured by SHIKOKU CHEMICALS CORPORATION, 1-benzyl-2-methyl imidazole)

### Component (g): Coupling Agent

(g-1) Z-6119 (product name, manufactured by Dow Toray Co., Ltd., 3-ureidopropyl triethoxysilane)

### <Preparation of Die Bonding Film>

A die bonding film was prepared by using each of the adhesive varnishes described above. Each of the adhesive varnishes was subjected to vacuum deaeration, and then, the adhesive varnish was applied onto a polyethylene terephthalate (PET) film (Thickness: 38 μm) subjected to a mold release treatment, which is a support film. The applied adhesive varnishes were heated and dried in two stages with different temperatures such as at 90° C. for 5 minutes, and subsequently, at 130° C. for 5 minutes to obtain die bonding films of Reference Example 1, Examples 1 to 3, and Comparative Examples 1 to 7, with a thickness of 25 μm in a stage B state, on the support film.

### <Calculation of % by Volume>

The content (% by volume) of the component (a) was calculated from Expression (I) described below when the density of the die bonding film was x (g/cm³), the density of the component (a) was y (g/cm³), and a mass ratio of the component (a) in the die bonding film was z (% by mass). Note that the mass ratio of the component (a) in the die bonding film was obtained by performing thermogravimetric analysis using a thermogravimeter-differential thermal analyzer (TG-DTA). In addition, the density of the die bonding film and the component (a) was obtained by measuring the mass and the specific weight using a gravimeter.

$$Content ( \% by volume ) of component ( a ) = ( x / y ) \times z \qquad ( I )$$

Measurement condition of TG-DTA: a temperature range of 30 to 600° C. (a temperature increase rate of 30° C./minute), maintained at 600° C. for 20 minutes
Air flow rate: 300 mL/minute
Thermogravimeter-differential thermal analyzer: manufactured by Seiko Instruments Inc., TG/DTA220
Gravimeter: manufactured by Alfa Mirage Co., Ltd., EW-300SG

### [Evaluation of Die Bonding Film (Measurement of Thermal Conductivity)]

### (Preparation of Film for Measuring Thermal Conductivity)

The die bonding film was cut to have a predetermined size, and eight film pieces of the die bonding films (Thickness: 25 μm) of Reference Example 1, Examples 1 to 3, and Comparative Examples 1 to 7 were prepared. Next, such film pieces were laminated on a hot plate at 70° C. using a rubber roll to prepare stacked bodies with a thickness of 200 μm. Next, each of the stacked bodies was thermally cured at 170° C. for 3 hours in a clean oven (manufactured by ESPEC CORP.) to obtain a specimen in a stage C state. The prepared specimen was cut to 1 cm×1 cm, which was used as a film for measuring a thermal conductivity to measure a thermal conductivity in the following measurement items/conditions. Results are shown in Table 1 and Table 2.

### (Calculation of Thermal Conductivity)

The thermal conductivity λ of the film for measuring a thermal conductivity in a thickness direction was calculated by the following expression.

$$Thermal conductivity λ ( W / m \cdot K ) = Thermal diffusivity α ( {m}^{2} / s ) \times Specific heat Cp ( J / kg \cdot K ) \times Density ρ ( g / {cm}^{3} )$$

Note that the thermal diffusivity α, the specific heat Cp, and the density ρ were measured by the following method. A high thermal conductivity λ indicates a more excellent heat dissipation property in a semiconductor device.

### (Measurement of Thermal Diffusivity α)

Both surfaces of the film for measuring a thermal conductivity were subjected to a blackening treatment by graphite spray to prepare a measurement sample. For the measurement sample, the thermal diffusivity α of the film for measuring a thermal conductivity was obtained by a laser flash method (a xenon flash method) using the following measurement device in the following condition.
Measurement device: a thermal diffusivity measurement device (manufactured by NETZSCH Japan K.K., product name: LFA447 nanoflash)
Pulse width of pulsed light irradiation: 0.1 ms
Applied voltage of pulsed light irradiation: 236 V
Treatment of measurement sample: both surfaces of the film for measuring a thermal conductivity were subjected to the blackening treatment by the graphite spray
Measurement ambient temperature: 25° C.±1° C.

### (Measurement of Specific Heat Cp (25° C.))

The specific heat Cp (25° C.) of the film for measuring a thermal conductivity was obtained by performing differential scanning calorimetry (DSC) using the following measurement device in the following condition.
Measurement device: a differential scanning calorimeter (manufactured by PerkinElmer Inc., product name: Pyris1)
Reference substance: sapphire
Temperature increase rate: 10° C./minute
Temperature increase range: a room temperature (25° C.) to 60° C.

### (Measurement of Density ρ)

The density ρ of the film for measuring a thermal conductivity was measured by Archimedes' principle using the following measurement device in the following condition.
Measurement device: an electronic gravimeter (manufactured by Alfa Mirage Co., Ltd., product name: SD200L)
Water temperature: 25° C.

TABLE 1

| | | Ref. Exam. 1 | Exam. 1 | Exam. 2 | Exam. 3 |
|---|---|---|---|---|---|
| Component (a) | (a-1) | 76.0 | 76.0 | 76.0 | 76.0 |
| Component (b) | (b-1) | — | 0.3 | 0.7 | 1.0 |
| Component (c) | (c-1) | 3.9 | 3.9 | 3.9 | 3.9 |
| | (c-2) | 5.8 | 5.8 | 5.8 | 5.8 |
| Component (d) | (d-1) | 7.9 | 7.9 | 7.9 | 7.9 |
| Component (e) | (e-1) | 6.4 | 6.4 | 6.4 | 6.4 |
| Component (f) | (f-1) | 0.005 | 0.005 | 0.005 | 0.005 |
| Component (g) | (g-1) | 0.025 | 0.025 | 0.025 | 0.025 |
| Content of | % by mass | 76.0 | 75.8 | 75.5 | 75.3 |
| component (a) | % by | 26.1 | 25.9 | 25.6 | 25.4 |
| (based on total | volume | | | | |
| amount of film) | | | | | |
| Thermal | W/m · k | 3.8 | 6.4 | 6.8 | 9.7 |
| conductivity | | | | | |

TABLE 2

| | | Comp. | Comp. | Comp. | Comp. | Comp. | Comp. | Comp. |
|---|---|---|---|---|---|---|---|---|
| | | Exam. 1 | Exam. 2 | Exam. 3 | Exam. 4 | Exam. 5 | Exam. 6 | Exam. 7 |
| Component (a) | (a-1) | 76.0 | 76.0 | 76.0 | 76.0 | 76.0 | 76.0 | 76.0 |
| Component (b′) | (b′-1) | 1.0 | — | — | — | — | — | — |
| | (b′-2) | — | 1.0 | — | — | — | — | — |
| | (b′-3) | — | — | 1.0 | — | — | — | — |
| | (b′-4) | — | — | — | 1.0 | — | — | — |
| | (b′-5) | — | — | — | — | 1.0 | — | — |
| | (b′-6) | — | — | — | — | — | 1.0 | — |
| | (b′-7) | — | — | — | — | — | — | 1.0 |
| Component (c) | (c-1) | 3.9 | 3.9 | 3.9 | 3.9 | 3.9 | 3.9 | 3.9 |
| | (c-2) | 5.8 | 5.8 | 5.8 | 5.8 | 5.8 | 5.8 | 5.8 |
| Component (d) | (d-1) | 7.9 | 7.9 | 7.9 | 7.9 | 7.9 | 7.9 | 7.9 |
| Component (e) | (e-1) | 6.4 | 6.4 | 6.4 | 6.4 | 6.4 | 6.4 | 6.4 |
| Component (f) | (f-1) | 0.005 | 0.005 | 0.005 | 0.005 | 0.005 | 0.005 | 0.005 |
| Component (g) | (g-1) | 0.025 | 0.025 | 0.025 | 0.025 | 0.025 | 0.025 | 0.025 |
| Content of | % by mass | 75.3 | 75.3 | 75.3 | 75.3 | 75.3 | 75.3 | 75.3 |
| component (a) | % by volume | 25.4 | 25.4 | 25.4 | 25.4 | 25.4 | 25.4 | 25.4 |
| (based on total | | | | | | | | |
| amount of film) | | | | | | | | |
| Thermal | W/m · k | 1.8 | 0.9 | 3.2 | 0.6 | 0.6 | 0.6 | 0.6 |
| conductivity | | | | | | | | |

As shown in Table 1, the die bonding films of Examples 1 to 3, which contained a glutaric acid, were excellent in the thermal conductivity, compared to the die bonding film of Reference Example 1, which did not contain the glutaric acid (other acids) or the like. In addition, as shown in Table 2, the die bonding films of Comparative Examples 1 to 7, which contained various acids, were not sufficient for the thermal conductivity, compared to the die bonding film of Reference Example 1, and an effect of improving such a thermal conductivity was determined as a specific effect exhibited when using the glutaric acid. As described above, it was checked that the dicing/die bonding integrated film of the present disclosure was capable of manufacturing the semiconductor device excellent in the heat dissipation property.

### REFERENCE SIGNS LIST

10: adhesive layer, 10A: die bonding film, 10a: adhesive layer piece, 10ac: cured product of adhesive layer piece, 12: adhesive member, 20: support film, 30, 30a: pressure-sensitive adhesive layer, 40: base material layer, 50: dicing tape, 60: semiconductor chip with adhesive layer piece, 70: wire, 72: needle, 74: suction collet, 80: support member, 92: sealing material layer, 94: solder ball, 100: dicing/die bonding integrated film, 200: semiconductor device, W: semiconductor wafer, Wa: semiconductor chip.

1. A method for manufacturing a die bonding film, comprising:
a first step of preparing a raw material varnish comprising silver-containing particles manufactured by a reductive method, a glutaric acid, and an organic solvent;
a second step of mixing the raw material varnish to obtain an adhesive varnish; and
a third step of applying the adhesive varnish to a support film, and removing the organic solvent to obtain a die bonding film,
wherein a content of the silver-containing particles is 70% by mass or more, on the basis of a total solid content of the adhesive varnish.

2. A method for manufacturing a die bonding film, comprising:
a first step of preparing a raw material varnish comprising silver-containing particles of which surfaces are treated with a surface treatment agent, a glutaric acid, and an organic solvent;
a second step of mixing the raw material varnish to obtain an adhesive varnish; and
a third step of applying the adhesive varnish to a support film, and removing the organic solvent to obtain a die bonding film,
wherein a content of the silver-containing particles is 70% by mass or more, on the basis of a total solid content of the adhesive varnish.

3. The method for manufacturing a die bonding film according to claim 1,
wherein the second step is a step of mixing the raw material varnish under a temperature condition of 50° C. or higher.

4. The method for manufacturing a die bonding film according to claim 1,
wherein the raw material varnish further comprises a thermosetting resin, a curing agent, and an elastomer.

5. The method for manufacturing a die bonding film according to claim 1,
wherein the second step is a step of adding a thermosetting resin, a curing agent, and an elastomer to the mixed raw material varnish to obtain an adhesive varnish further comprising the thermosetting resin, the curing agent, and the elastomer.

6. A method for manufacturing a dicing/die bonding integrated film, comprising:
preparing a dicing tape having a base material layer and a pressure-sensitive adhesive layer provided on the base material layer; and
sticking the die bonding film manufactured by the method for manufacturing a die bonding film according to claim 1 and the pressure-sensitive adhesive layer of the dicing tape to form an adhesive layer consisting of the die bonding film on the pressure-sensitive adhesive layer.

7. A method for manufacturing a semiconductor device, comprising:
sticking the adhesive layer of the dicing/die bonding integrated film manufactured by the method for manufacturing a dicing/die bonding integrated film according to claim 6 to a semiconductor wafer;
singulating the semiconductor wafer and the adhesive layer;
picking up a semiconductor chip with an adhesive layer piece from the dicing tape; and
causing the semiconductor chip with an adhesive layer piece to adhere to a support member via the adhesive layer piece.

8. A die bonding film, comprising:
silver-containing particles manufactured by a reductive method; and
a glutaric acid,
wherein a content of the silver-containing particles is 70% by mass or more, on the basis of a total amount of the die bonding film.

9. The die bonding film according to claim 8, further comprising:
a thermosetting resin;
a curing agent; and
an elastomer.

10. The die bonding film according to claim 9,
wherein the thermosetting resin comprises an epoxy resin that is liquid at 25° C.

11. A dicing/die bonding integrated film, comprising:
a dicing tape having a base material layer and a pressure-sensitive adhesive layer provided on the base material layer; and
an adhesive layer consisting of the die bonding film according to claim 8, disposed on the pressure-sensitive adhesive layer of the dicing tape.

12. The method for manufacturing a die bonding film according to claim 2,
wherein the second step is a step of mixing the raw material varnish under a temperature condition of 50° C. or higher.

13. The method for manufacturing a die bonding film according to claim 2,
wherein the raw material varnish further comprises a thermosetting resin, a curing agent, and an elastomer.

14. The method for manufacturing a die bonding film according to claim 2,
wherein the second step is a step of adding a thermosetting resin, a curing agent, and an elastomer to the mixed raw material varnish to obtain an adhesive varnish further comprising the thermosetting resin, the curing agent, and the elastomer.

15. A method for manufacturing a dicing/die bonding integrated film, comprising:
preparing a dicing tape having a base material layer and a pressure-sensitive adhesive layer provided on the base material layer; and
sticking the die bonding film manufactured by the method for manufacturing a die bonding film according to claim 2 and the pressure-sensitive adhesive layer of the dicing tape to form an adhesive layer consisting of the die bonding film on the pressure-sensitive adhesive layer.

16. A method for manufacturing a semiconductor device, comprising:
sticking the adhesive layer of the dicing/die bonding integrated film manufactured by the method for manufacturing a dicing/die bonding integrated film according to claim 15 to a semiconductor wafer;
singulating the semiconductor wafer and the adhesive layer;
picking up a semiconductor chip with an adhesive layer piece from the dicing tape; and
causing the semiconductor chip with an adhesive layer piece to adhere to a support member via the adhesive layer piece.

17. A dicing/die bonding integrated film, comprising:
a dicing tape having a base material layer and a pressure-sensitive adhesive layer provided on the base material layer; and
an adhesive layer consisting of the die bonding film according to claim 9, disposed on the pressure-sensitive adhesive layer of the dicing tape.

18. A dicing/die bonding integrated film, comprising:
a dicing tape having a base material layer and a pressure-sensitive adhesive layer provided on the base material layer; and
an adhesive layer consisting of the die bonding film according to claim 10, disposed on the pressure-sensitive adhesive layer of the dicing tape.

19. The method for manufacturing a die bonding film according to claim 1,
wherein the content of the glutaric acid is 0.1 to 5 parts by mass when the total amount of the silver-containing particles is 100 parts by mass.

20. The method for manufacturing a die bonding film according to claim 2,
wherein the content of the glutaric acid is 0.1 to 5 parts by mass when the total amount of the silver-containing particles is 100 parts by mass.
